(19) United States
(12) Patent Application Publication
(10) Pub. No.: US 2009/0224303 A1
(43) Pub. Date: Sep. 10, 2009

(54) High voltage capacitor and manufacture method thereof

(75) Inventor: Jui-Chang Lin, Taichung County (TW)

Correspondence Address: RABIN & Berdo, PC, 1101 14TH STREET, NW, SUITE 500, WASHINGTON, DC, 20005, US

(73) Assignee: NOVATEK MICROELECTRONICS CORP., HsinChu (TW)

(21) Appl. No.: 12/216,667

(22) Filed: Jul. 9, 2008

(30) Foreign Application Priority Data
Mar. 6, 2008 (TW) 097107951

(51) Int. Cl. H01L 21/02; H01L 29/94

(52) U.S. Cl. 257/296; 438/381; 257/E29.345; 257/E21.008

(57) ABSTRACT

A high voltage capacitor and a manufacture method thereof are provided. The high voltage capacitor comprises a double diffused drain layer, an oxide layer and a poly-crystal silicon layer. The double diffused drain layer is used as a bottom electrode plate of a high voltage capacitor. The oxide layer is formed on the double diffused drain layer, and is completely overlapped on the double diffused drain layer. The poly-crystal silicon layer is formed on the oxide layer, and is used as a top electrode plate of the high voltage capacitor.

This application claims the benefit of Taiwan application Serial No. 97107951, filed Mar. 6, 2008, the subject matter of which is incorporated herein by reference.

### BACKGROUND OF THE INVENTION

1. Field of the Invention

The invention relates in general to a high voltage capacitor, and more particularly to a high voltage capacitor using smaller area of circuit layout area and a manufacture method thereof.

2. Description of the Related Art

The capacitor used in an ordinary liquid crystal display driver integrated circuit is normally a high voltage capacitor capable of receiving high voltages. Examples of high voltage capacitor include polysilicon-insulator-polysilicon (PIP) capacitor, metal-insulator-metal (MIM) capacitor and metal oxide semiconductor (MOS) capacitor.

Both PIP capacitor and MIM capacitor require additional masks or manufacturing steps in a semiconductor manufacturing process. PIP capacitor manufacturing process is a front end manufacturing process, which affects the adjustment of element properties and is not easy to go with advanced manufacturing process (such as 0.18 um below). MIM capacitor employs plasma enhanced chemical vapor deposition (PECVD) thin film, and the properties of MIM capacitor are inferior to that of PIP capacitor and MOS capacitor.

If high voltage MOS capacitor is used, the number of masks and manufacturing steps can be reduced and best capacitor properties are produced. For neighboring MOS capacitors to be operated independently, normally wells are used as a means of isolation. The wells must be capable of receiving high voltages. Therefore, the area of circuit layout for MOS capacitor is larger than that for PIP capacitor or MIM capacitor.

### SUMMARY OF THE INVENTION

The invention is directed to a high voltage capacitor and a manufacture method thereof. The high voltage capacitor of the invention not only can do without using additional masks or manufacturing steps but also reduce the area of circuit layout.

According to a first aspect of the present invention, a method of manufacture a high voltage capacitor is provided. The manufacture method comprises the following steps. Firstly, a double diffused drain (DDD) layer is formed as a bottom electrode plate of the high voltage capacitor. Next, an oxide layer is formed on the double diffused drain layer and completely overlapped on the double diffused drain layer. Then, a poly-crystal silicon layer is formed on the oxide layer as a top electrode plate of the high voltage capacitor.

According to a second aspect of the present invention, a high voltage capacitor is provided. The high voltage capacitor comprises a double diffused drain layer, an oxide layer and a poly-crystal silicon layer. The double diffused drain layer is used as a bottom electrode plate of a high voltage capacitor. The oxide layer is formed on the double diffused drain layer, and is completely overlapped on the double diffused drain layer. The poly-crystal silicon layer is formed on the oxide layer, and is used as a top electrode plate of the high voltage capacitor.

The invention will become apparent from the following detailed description of the preferred but non-limiting embodiments. The following description is made with reference to the accompanying drawings.

### BRIEF DESCRIPTION OF THE DRAWINGS

FIG. 1 shows a partial perspective of a high voltage MOS capacitor;

FIG. 2 shows a top view of the high voltage MOS capacitor;

FIG. 3 shows a partial perspective of a high voltage capacitor;

FIG. 4 shows a top view of a high voltage capacitor 3; and

FIG. 5 shows a flowchart of a method of manufacture a high voltage capacitor.

### DETAILED DESCRIPTION OF THE INVENTION

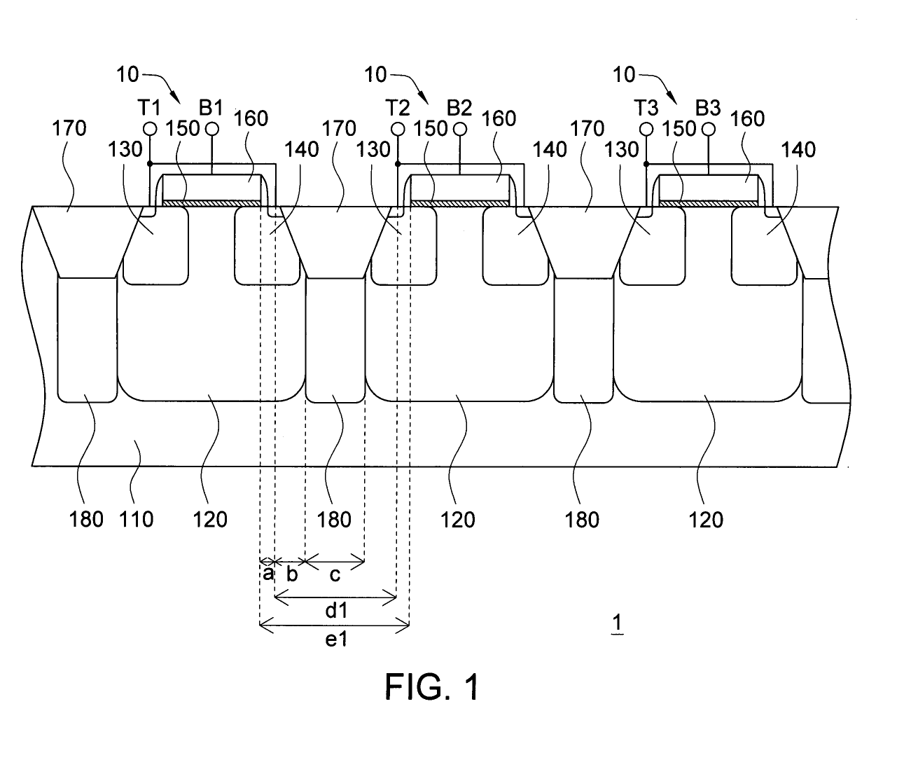

Referring to FIG. 1, a partial perspective of a high voltage MOS capacitor is shown. On the part of the high voltage MOS capacitor 1, multiple high voltage MOS capacitors 10 are respectively formed between the connecting point T1 and the connecting point B1, between the connecting point T2 and the connecting point B2, and between the connecting point T3 and the connecting point B3. Multiple wells 120 are formed on a substrate 110, and two double diffused drain (DDD) structures 130 and 140 are formed on each well 120 and respectively used as a drain and a source. The drain and the source are electrically connected. Next, an oxide layer 150 is formed on each well 120 and on part of the drain and part of the source. Lastly, a poly-crystal silicon layer 160 covers the oxide layer 150 and is used as a gate.

Every two neighboring high voltage MOS capacitors 10 are separated by an isolation element 170 and a well 180. Examples of the isolation element 170 include shallow trench isolation (STI) and field oxide (FOX) layer. As the high voltage MOS capacitor 10 must receive high voltage, the interval c between the well 120 and its neighboring well 120 must have a larger length.

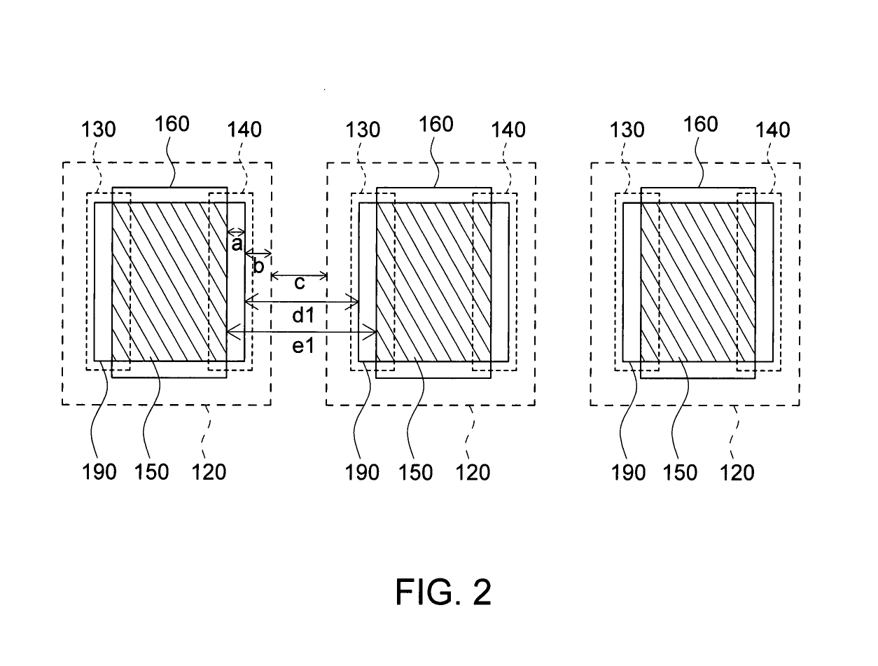

Referring to FIG. 2, a top view of the high voltage MOS capacitor is shown. Each high voltage MOS capacitor 10 respectively has an active region 190 (also called as diffusion region). The active region 190 and the poly-crystal silicon layer 160 are apart by an interval a, and the active region 190 and the well 120 are apart by an interval b. Furthermore, every two neighboring wells 120 are apart by the interval b, every two neighboring active regions 190 are apart by an interval d1, and every two neighboring poly-crystal silicon layers 160 are apart by an interval e1.

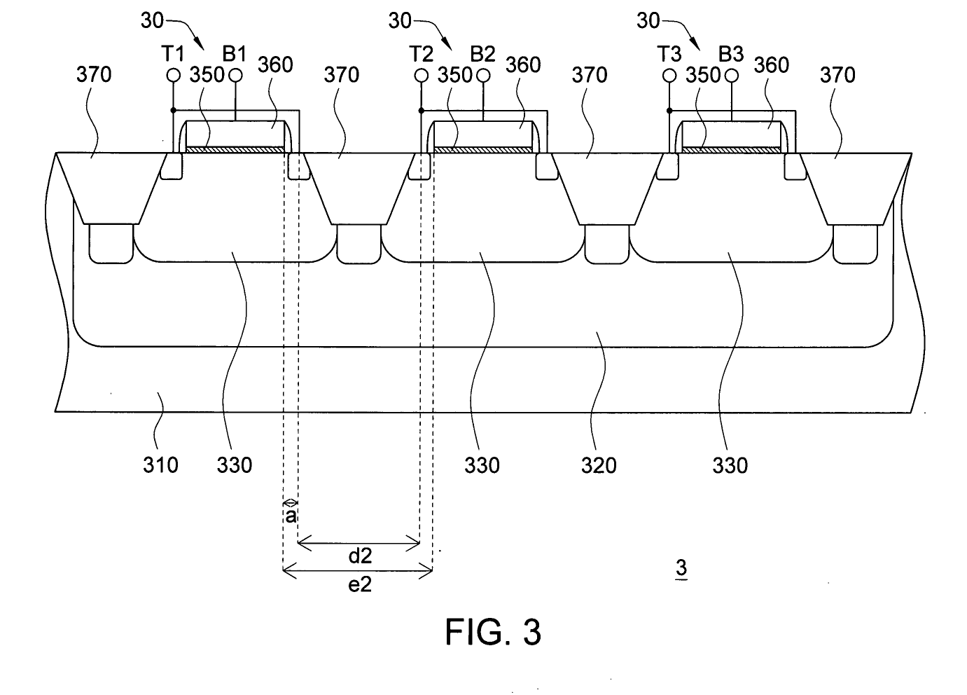

Referring to FIG. 3, a partial perspective of a high voltage capacitor is shown. The high voltage capacitor 3 is used as a high voltage element in a liquid crystal display driver integrated circuit. The high voltage capacitor 3 comprises a substrate 310, a well 320, a double diffused drain (DDD) layer 330, an oxide layer 350, a poly-crystal silicon layer 360 and a isolation element 370. A well 320 is formed on a substrate 310A, and a double diffused drain layer 330 is formed on the well 320 ├ as a bottom electrode plate of a high voltage capacitor.

An oxide layer 350 formed on the double diffused drain layer 330 for storing electric charges is completely overlapped on the double diffused drain layer 330. A poly-crystal silicon layer 360 formed on the oxide layer 350 is used as a top electrode plate of the high voltage capacitor. An isolation element 370 is formed between every two neighboring double diffused drain layers 330. Examples of the isolation element 370 include shallow trench isolation (STI) and field oxide (FOX) layer.

The double diffused drain layers 330, the oxide layers 350 and the poly-crystal silicon layers 360 are stacked to form one high voltage capacitor 30. For example, one high voltage capacitor 30 is formed between the connecting point T1 and the connecting point B1, another high voltage capacitor 30 is formed between the connecting point T2 and the connecting point B2, and another high voltage capacitor 30 is further formed between the connecting point T3 and the connecting point B3. Each high voltage capacitor 30 can be operated independently.

As two double diffused drain (DDD) structures need to be formed as a drain and a source during the original semiconductor manufacturing process, the high voltage capacitor 3 can be formed without using additional masks or manufacturing steps. Besides, on the part of the high voltage capacitor 3, the interval b between two neighboring poly-crystal silicon layers 360 is far smaller than the interval e1 in the high voltage MOS capacitor 1.

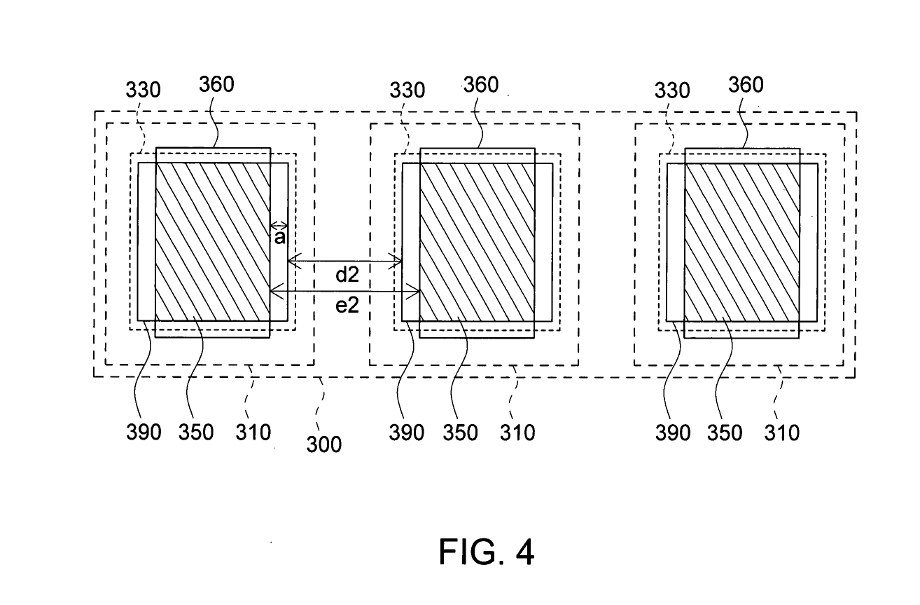

Referring to FIG. 4, a top view of a high voltage capacitor 3 is shown. Each high voltage capacitor 30 respectively has an active region (also called diffusion region). The active region 390 and the poly-crystal silicon layer 360 are apart by an interval a, every two neighboring active region 390 are apart by an interval d2, and every two neighboring poly-crystal silicon layer 360 are apart by an interval e2.

The interval e1 is the sum of double interval a, double interval b and the interval c, and the interval e2 is the sum of double interval a and the interval d2. As on the part of the high voltage MOS capacitor 1, the interval b and the interval c are respectively larger than the interval d2 of the high voltage capacitor 3, the interval e2 is far smaller than the interval e1. Thus, the area of the circuit layout of the high voltage capacitor 3 will be far smaller than the high voltage MOS capacitor 1. Compared with the high voltage MOS capacitor 1, the high voltage capacitor 3 is even more suitable to the driver integrated circuit having a large number of pins.

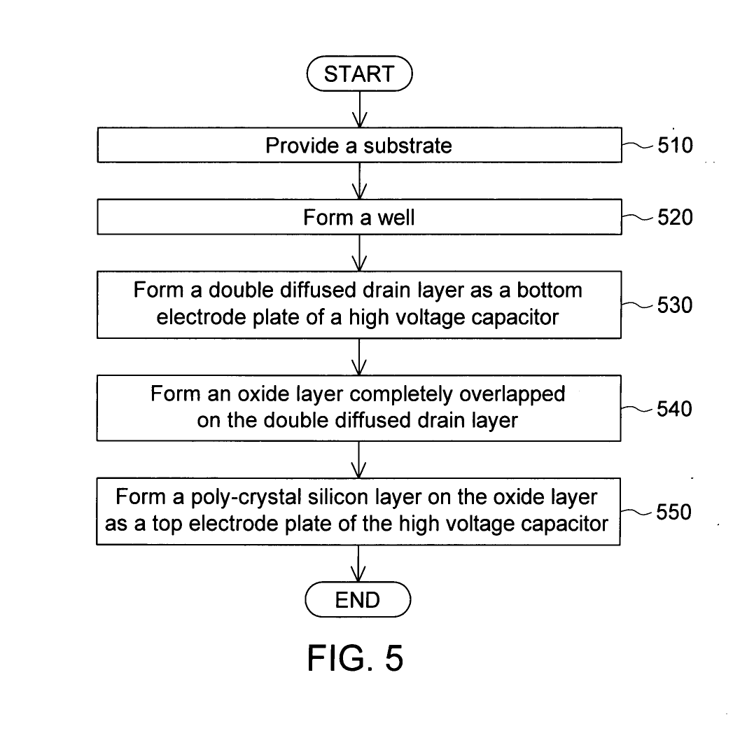

Referring to FIG. 5, a flowchart of a method of manufacture a high voltage capacitor is shown. The method of manufacture a high voltage capacitor is applicable to the manufacturing of the high voltage capacitor 3. The manufacture method comprises the following steps:

Firstly, the method begins at step 510, a substrate 310 is provided. Next, the method proceeds to step 520, a well 320 is formed. Then, the method proceeds to step 530, a double diffused drain layer 330 is formed as a bottom electrode plate of a high voltage capacitor. After that, the method proceeds to step 540, an oxide layer 350 is formed on the double diffused drain layer 330 and completely overlapped on the double diffused drain layer 330.

Lastly, the method proceeds to step 550, a poly-crystal silicon layer 360 is formed on the oxide layer 350 as a top electrode plate of the high voltage capacitor.

The high voltage capacitor and the manufacture method thereof disclosed in the above embodiments of the invention do not require any additional masks or manufacturing steps and further reduce the area of circuit layout.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacture a high voltage capacitor, the method comprising:
forming a double diffused drain (DDD) layer as a bottom electrode plate of a high voltage capacitor;
forming an oxide layer on the double diffused drain layer, wherein the oxide layer is completely overlapped on the double diffused drain layer; and
forming a poly-crystal silicon layer on the oxide layer as a top electrode plate of the high voltage capacitor.

2. The manufacture method according to claim 1, further comprising:
providing a substrate; and
forming a first well on the substrate for forming the double diffused drain layer.

3. The manufacture method according to claim 2, further comprising:
forming another double diffused drain (DDD) layer on the first well as a bottom electrode plate of another high voltage capacitor;
forming another oxide layer on the other double diffused drain layer, wherein the other oxide layer is completely overlapped on the other double diffused drain layer; and
forming another poly-crystal silicon layer on the other oxide layer as a top electrode plate of the high voltage capacitor.

4. The manufacture method according to claim 3, further comprising:
forming an isolation element between the double diffused drain layer and the other double diffused drain layer.

5. The manufacture method according to claim 4, wherein the isolation element is a shallow trench isolation (STI) layer.

6. The manufacture method according to claim 4, wherein the isolation element is a field oxide (FOX) layer.

7. The manufacture method according to claim 1, the high voltage capacitor is used in a liquid crystal display driver integrated circuit.

8. A high voltage capacitor, comprising:
a double diffused drain (DDD) layer used as a bottom electrode plate of a high voltage capacitor;
an oxide layer formed on the double diffused drain layer, wherein the oxide layer is completely overlapped on the double diffused drain layer; and
a poly-crystal silicon layer formed on the oxide layer and used as a top electrode plate of the high voltage capacitor.

9. The high voltage capacitor according to claim 8, wherein the double diffused drain layer is formed on a first well, which is formed on a substrate.

10. The high voltage capacitor according to claim 9, wherein another double diffused drain (DDD) layer is formed on the first well as a bottom electrode plate of another high voltage capacitor.

11. The high voltage capacitor according to claim 10, wherein the other double diffused drain layer forms another oxide layer completely overlapped on the other double diffused drain layer.

12. The high voltage capacitor according to claim 11, wherein another poly-crystal silicon layer is formed on the other oxide layer as a top electrode plate of the high voltage capacitor.

13. The high voltage capacitor according to claim 12, wherein an isolation element is formed between the double diffused drain layer and the other double diffused drain layer.

14. The high voltage capacitor according to claim 13, wherein the isolation element is a shallow trench isolation (STI) layer.

15. The high voltage capacitor according to claim 13, wherein the isolation element is a field oxide (FOX) layer.

16. The high voltage capacitor according to claim 8, wherein the high voltage capacitor is used in a liquid crystal display driver integrated circuit.
